(19) United States
(12) Patent Application Publication
(10) Pub. No.: US 2026/0031120 A1
(43) Pub. Date: Jan. 29, 2026

(54) MEMORY INTERFACE CIRCUITS FOR PERFORMING PRE-EMPHASIS OPERATIONS AND METHODS OF OPERATING THE SAME

(71) Applicant: Samsung Electronics Co., Ltd., Suwon-si (KR)

(72) Inventors: Sangyoon Lee, Suwon-si (KR); Jaewoo Lee, Suwon-si (KR); Daesik Moon, Suwon-si (KR); Kihan Kim, Suwon-si (KR)

(21) Appl. No.: 19/202,303

(22) Filed: May 8, 2025

(30) Foreign Application Priority Data
Jul. 25, 2024 (KR) 10-2024-0098800

(51) Int. Cl. G11C 7/22; G11C 7/10

(52) U.S. Cl. CPC G11C 7/222; G11C 7/106; G11C 7/1066; G11C 2207/2254

(57) ABSTRACT

A memory interface circuit includes a calibration loop circuit configured to generate: a first pulse signal in response to a first clock signal, a second pulse signal in response to the first clock signal and a second clock signal, a delay signal by inverting and delaying the first pulse signal using a first variable capacitor, and a delay code based on the first and second pulse signals and the delay signal. A first transmitter is provided, and configured to generate a transmission signal in response to a data signal received from a volatile memory device, and perform a pre-emphasis operation on the transmission signal based on a capacitance of a second variable capacitor, which changes in response to changes in the delay code.

### REFERENCE TO PRIORITY APPLICATION

This application claims priority under 35 U.S.C. § 119 to Korean Patent Application No. 10-2024-0098800, filed July 25, 2024, the disclosure of which is hereby incorporated herein by reference.

### BACKGROUND

Embodiments of the present disclosure described herein relate to memory devices and, more particularly, to memory interface circuits and methods of operating the same.

A memory device stores data in response to a write request and outputs data stored therein in response to a read request. A memory device is typically classified as a volatile memory device, which loses data stored therein when power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

The memory device may communicate with a host device. For example, the memory device may receive data from the host device connected to a memory interface circuit through a plurality of channels or may output data to the host device. When the memory interface circuit transmits data to be stored in the memory device to the host device, there may be required a technique for minimizing the distortion of the data being transmitted.

### SUMMARY

Embodiments of the present disclosure provide memory interface circuits configured to perform pre-emphasis operations and methods of operating the same.

According to an embodiment, a memory interface circuit includes a calibration loop circuit configured to generate: a first pulse signal in response to a first clock signal, a second pulse signal in response to the first clock signal and a second clock signal, a delay signal by inverting and delaying the first pulse signal using a first variable capacitor, and a delay code based on the first and second pulse signals and the delay signal; and a first transmitter configured to generate a transmission signal in response to a data signal received from a volatile memory device, and perform a pre-emphasis operation on the transmission signal based on a capacitance of a second variable capacitor, which changes in response to changes in the delay code.

According to an embodiment, a method of operating a memory interface circuit including a pad, a calibration loop circuit, and a transmitter includes: receiving, by the calibration loop circuit, a first clock signal and a second clock signal, generating, by the calibration loop circuit, a first pulse signal based on the first clock signal, generating, by the calibration loop circuit, a second pulse signal based on the first clock signal and the second clock signal, generating, by the calibration loop circuit, a delay signal by inverting the first pulse signal and delaying the inverted first pulse signal by using a first variable capacitor, generating, by the calibration loop circuit, a delay code for controlling a second variable capacitor based on the first pulse signal, the second pulse signal, and the delay signal, receiving, by the transmitter, a data signal from a volatile memory device, generating, by the transmitter, a transmission signal based on the data signal, and performing, by the transmitter, a pre-emphasis operation on the transmission signal based on a capacitance value of the second variable capacitor, which is changed depending on the delay code. The calibration loop circuit can include the first variable capacitor, and the transmitter can include the second variable capacitor.

According to an embodiment, a memory interface circuit includes a pad that is connected to an external device, a calibration loop circuit that includes a first group of a plurality of transistors, and a transmitter that is connected to the pad and includes a second group of a plurality of transistors. The calibration loop circuit receives a first clock signal and a second clock signal, generates a first pulse signal based on the first clock signal, generates a second pulse signal based on the first clock signal and the second clock signal, generates a delay signal by delaying the first pulse signal by using the first group of the plurality of transistors, and generates a delay code for controlling the second group of the plurality of transistors based on the first pulse signal, the second pulse signal, and the delay signal. The transmitter receives a data signal from a volatile memory device, generates a transmission signal based on the data signal, and performs a pre-emphasis operation on the transmission signal by using the second group of the plurality of transistors controlled by the delay code.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic system according to an embodiment of the present disclosure.

FIG. 2 is a block diagram of a memory interface circuit according to an embodiment of the present disclosure.

FIG. 3 is a block diagram of a calibration loop circuit according to some embodiments of the present disclosure.

FIG. 4 is a flowchart describing a method of operating a calibration loop circuit according to some embodiments of the present disclosure.

FIG. 5 is a timing diagram describing signals which a calibration loop circuit according to some embodiments of the present disclosure generates.

FIG. 6 is a block diagram of a transmitter according to some embodiments of the present disclosure.

FIG. 7 is a timing diagram describing signals which a transmitter according to some embodiments of the present disclosure generates.

FIG. 8 is a diagram describing a pre-emphasis logic circuit according to some embodiments of the present disclosure.

FIG. 9 is a diagram describing a variable capacitor according to some embodiments of the present disclosure.

FIG. 10 is a diagram describing a pre-emphasis logic circuit according to some embodiments of the present disclosure.

FIG. 11 is a diagram describing a pre-emphasis circuit according to some embodiments of the present disclosure.

FIG. 12 is a block diagram of a memory interface circuit according to some embodiments of the present disclosure.

FIG. 13 is a flowchart describing a method of operating a memory interface circuit according to some embodiments of the present disclosure.

### DETAILED DESCRIPTION

Below, embodiments of the present disclosure will be described in detail and clearly to such an extent that one of ordinary skill in the art can make the claimed invention without undue experimentation.

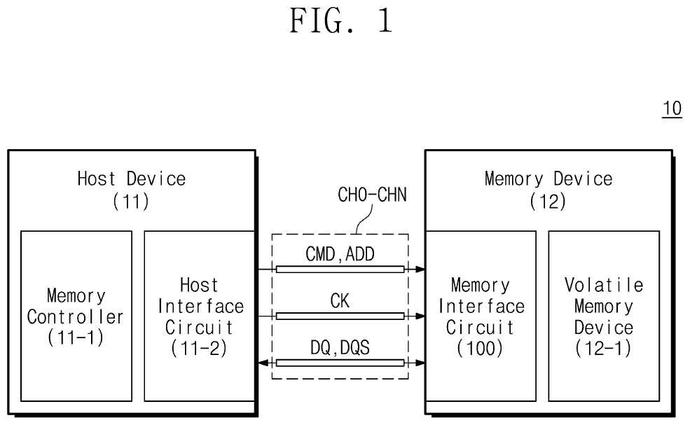

FIG. 1 is a block diagram of an electronic system according to an embodiment of the present disclosure. Referring to FIG. 1, an electronic device 10 may include a computing system configured to process a variety of information or to store the processed information as data. In some embodiments, the electronic device 10 may be implemented with a personal computer (PC), a notebook, a laptop, a server, a workstation, a tablet PC, a smartphone, a digital camera, a black box, etc. The electronic device 10 may include a host device 11 and a memory device 12.

The host device 11 may store data in the memory device 12 or may read data stored in the memory device 12. For example, the host device 11 may transmit a clock signal CK, a command signal CMD, and an address signal ADD to the memory device 12 and may exchange a transmission signal DQ and a data strobe signal DQS with the memory device 12. In some embodiments, the host device 11 and the memory device 12 may communicate with each other based on a double data rate (DDR) interface or a low-power DDR (LP DDR) interface, but the present disclosure is not limited thereto.

The host device 11 may include a memory controller 11-1 and a host interface circuit 11-2. The memory controller 11-1 may control all the operations of the memory device 12. The host interface circuit 11-2 may communicate with a memory interface circuit 100 of the memory device 12. For example, the host interface circuit 11-2 may communicate with the memory interface circuit 100 through a plurality of channels CH0 to CHN. Through the plurality of channels CH0 to CHN, the host interface circuit 11-2 may transmit the transmission signal DQ and the data strobe signal DQS to the memory interface circuit 100 or may receive the transmission signal DQ and the data strobe signal DQS from the memory interface circuit 100.

In some embodiments, the host interface circuit 11-2 may perform impedance matching with the memory interface circuit 100 at the end of the plurality of channels CH0 to CHN (e.g., to reduce undesirable signal reflections). For example, the host interface circuit 11-2 may include a matching circuit (e.g., a matching circuit including a resistor and a transistor) for impedance matching with the memory interface circuit 100 at the end of the plurality of channels CH0 to CHN.

The plurality of channels CH0 to CHN may be provided between the host device 11 and the memory device 12. For example, the plurality of channels CH0 to CHN may refer to signal lines which connect the host interface circuit 11-2 of the host device 11 and the memory interface circuit 100 of the memory device 12. In an embodiment, “N” is an arbitrary natural number. The memory device 12 may include a volatile memory device 12-1 and the memory interface circuit 100. The volatile memory device 12-1 may be implemented with a volatile memory device, which loses data stored therein when a power is turned off, such as a dynamic random access memory (DRAM) or a static random access memory (SRAM). The volatile memory device 12-1 may store data and may provide the stored data to the host device 11. For example, the volatile memory device 12-1 may provide data to the host device 11 through the memory interface circuit 100.

The memory interface circuit 100 may communicate with the host interface circuit 11-2 of the host device 11. For example, the memory interface circuit 100 may communicate with the host interface circuit 11-2 through the plurality of channels CH0 to CHN. As shown, the memory interface circuit 100 may provide the volatile memory device 12-1 with the clock signal CK, the command signal CMD, and the address signal ADD received from the host interface circuit 11-2. Also, the memory interface circuit 100 may provide the volatile memory device 12-1 with the transmission signal DQ and the data strobe signal DQS received from the host interface circuit 11-2 or may transmit the transmission signal DQ and the data strobe signal DQS received from the volatile memory device 12-1 to the host interface circuit 11-2.

The distortion of a signal (e.g., the clock signal CK, the command signal CMD, the address signal ADD, the transmission signal DQ, or the data strobe signal DQS) may occur on the plurality of channels CH0 to CHN through which the memory interface circuit 100 and the host interface circuit 11-2 communicate with each other. For example, the transmission signal DQ which the memory interface circuit 100 transmits to the host interface circuit 11-2 through the plurality of channels CH0 to CHN may be distorted.

In some embodiments, the memory interface circuit 100 may perform impedance matching with the host interface circuit 11-2 at the end of the plurality of channels CH0 to CHN. For example, the memory interface circuit 100 may include a matching circuit (e.g., a matching circuit including a resistor and a transistor) for impedance matching with the host interface circuit 11-2 at the end of the plurality of channels CH0 to CHN.

The memory interface circuit 100 may perform a pre-emphasis operation on the transmission signal DQ. The pre-emphasis operation may refer to an operation of emphasizing a portion of the transmission signal DQ before the signal transmission such that the deformation of the transmission signal DQ due to the distortion during transmission is minimized. The pre-emphasis operation which the memory interface circuit 100 performs will be described in detail later.

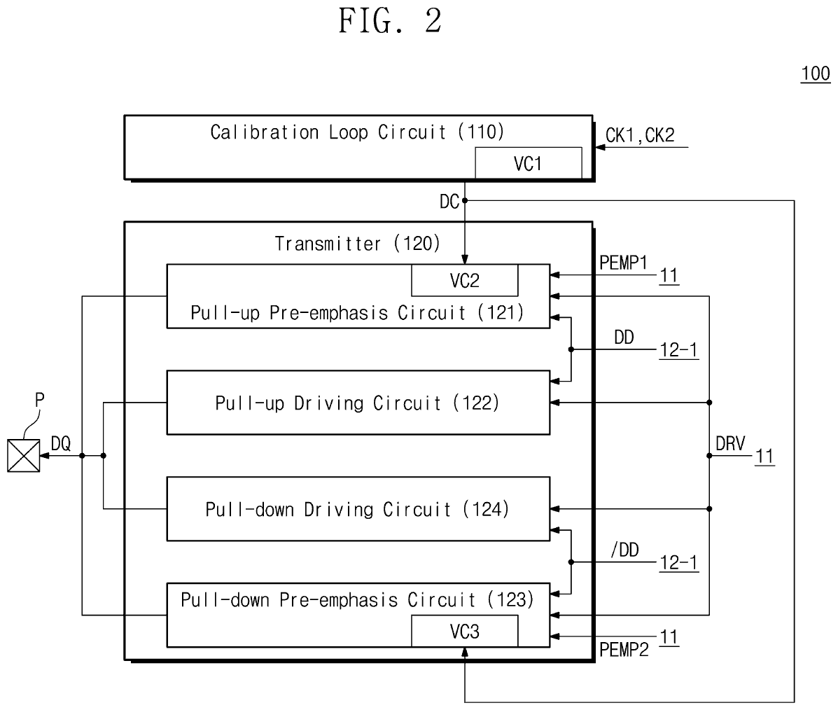

FIG. 2 is a block diagram of a memory interface circuit according to an embodiment of the present disclosure. Referring to FIG. 2, the memory interface circuit 100 may include a calibration loop circuit 110 and a transmitter 120. The calibration loop circuit 110 may generate a delay code DC. For example, the calibration loop circuit 110 may generate the delay code DC for controlling a second variable capacitor VC2 and a third variable capacitor VC3 of the transmitter 120. In some embodiments, the calibration loop circuit 110 may generate the delay code DC which allows the second variable capacitor VC2 of the transmitter 120 to delay a data signal DD such that there is generated a driving signal (for controlling an output driver) including a pulse whose pulse width is similar to a unit interval (hereinafter referred to as “1 UI”).

The 1 UI may correspond to a phase difference of clock signals. For example, the 1 UI may correspond to a phase difference of a first clock signal CK1 whose phase is 0° and a second clock signal CK2 whose phase is 90°. However, the phases of the first clock signal CK1 and the second clock signal CK2 are provided only for better understanding and are not intended to limit the scope of the present disclosure. The first clock signal CK1 and the second clock signal CK2 may have phases which are different from the above phases and have the phase difference of 90°. The first clock signal CK1 and the second clock signal CK2 may be clocks which are generated (e.g., divided) by the memory interface circuit 100 based on the clock signal CK of FIG. 1 received from the host device 11 (e.g., may be one of quadrature clock signals).

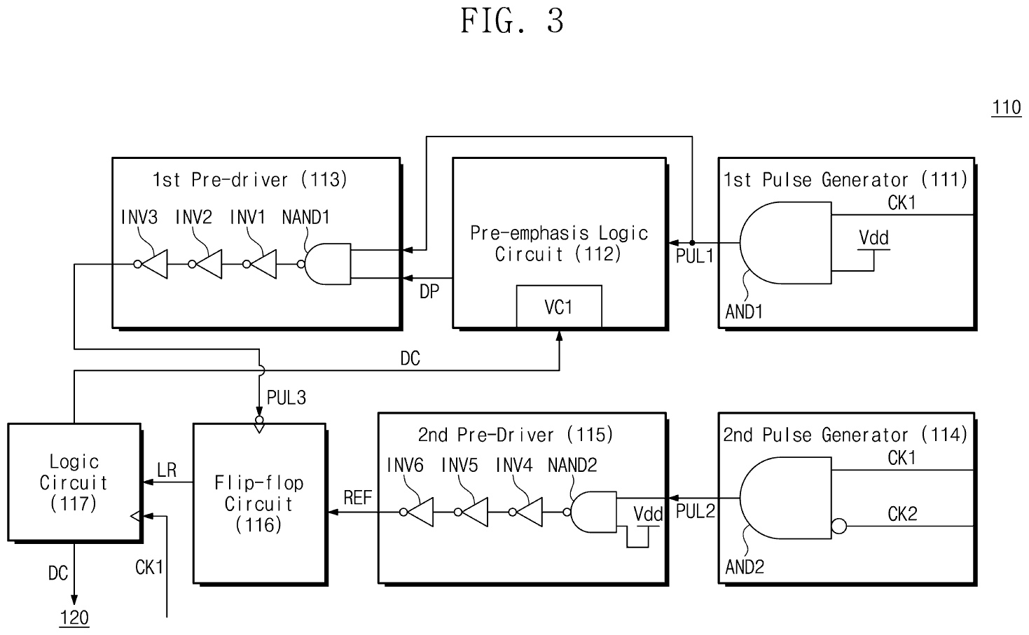

The calibration loop circuit 110 may include a first variable capacitor VC1. The first variable capacitor VC1 may operate based on the delay code DC. For example, the capacitance value of the first variable capacitor VC1 may change based on the delay code DC. To generate the delay code DC for controlling the second variable capacitor VC2 and the third variable capacitor VC3, the calibration loop circuit 110 may use the first variable capacitor VC1 (identical or similar to the second variable capacitor VC2 and/or the third variable capacitor VC3). The first variable capacitor VC1 will be described in detail with reference to FIG. 3.

The calibration loop circuit 110 may generate the delay code DC based on the first clock signal CK1 and the second clock signal CK2. For example, the calibration loop circuit 110 may generate a plurality of signals based on the first clock signal CK1 and the second clock signal CK2 and may generate the delay code DC based on the plurality of signals. Below, the plurality of signals which the calibration loop circuit 110 generates may be described with reference to FIG. 3.

In some embodiments, the calibration loop circuit 110 may generate a first pulse signal (not illustrated) based on the first clock signal CK1. For example, the calibration loop circuit 110 may generate the first pulse signal (not illustrated) whose pulse width is identical or similar to the 2 UI, based on the first clock signal CK1.

In some embodiments, the calibration loop circuit 110 may generate a second pulse signal (not illustrated) based on the first clock signal CK1 and the second clock signal CK2. For example, the calibration loop circuit 110 may generate the second pulse signal (not illustrated) corresponding to the phase difference of the first clock signal CK1 and the second clock signal CK2. The second pulse signal (not illustrated) may include pulses which are identical to the phase difference of the first clock signal CK1 and the second clock signal CK2.

In some embodiments, the calibration loop circuit 110 may generate a delay signal (not illustrated) by inverting and delaying the first pulse signal (not illustrated) by using the first variable capacitor VC1. In some embodiments, the calibration loop circuit 110 may generate the delay code DC for controlling the second variable capacitor VC2 based on the first pulse signal (not illustrated), the second pulse signal (not illustrated), and the delay signal (not illustrated). For example, to generate driving signals (not illustrated), whose pulse width is similar to the 1 UI, based on the first pulse signal (not illustrated), the second pulse signal (not illustrated), and the delay signal (not illustrated), the calibration loop circuit 110 may generate the delay code DC for controlling the second variable capacitor VC2 and the third variable capacitor VC3. The 1 UI may be identical to the phase difference of the first and second clock signals CK1 and CK2. In some embodiments, the calibration loop circuit 110 may generate a third pulse signal (not illustrated) corresponding to the phase difference of the first pulse signal (not illustrated) and the delay signal (not illustrated). Also, the calibration loop circuit 110 may generate a reference signal (not illustrated) with a pulse width of the 1UI based on the second pulse signal (not illustrated). Next, the calibration loop circuit 110 may generate a result signal (not illustrated) based on a result of comparing the third pulse signal (not illustrated) and the reference signal (not illustrated). The calibration loop circuit 110 may generate the delay code DC based on a logic level of the result signal (not illustrated). The calibration loop circuit 110 will be described in more detail hereinbelow with reference to FIG. 3.

The transmitter 120 may output the transmission signal DQ. For example, the transmitter 120 may generate the transmission signal DQ based on the data signal DD and an inverted data signal/DD received from the volatile memory device 12-1 and may transmit the transmission signal DQ to the host device 11 through a pad “P”. The transmitter 120 may include a pull-up pre-emphasis circuit 121, a pull-up driving circuit 122, a pull-down pre-emphasis circuit 123, and a pull-down driving circuit 124. Output terminals of the pull-up pre-emphasis circuit 121, the pull-up driving circuit 122, the pull-down pre-emphasis circuit 123, and the pull-down driving circuit 124 may be connected to the pad “P”. The pull-up pre-emphasis circuit 121 may perform the pre-emphasis operation on the transmission signal DQ. For example, the pull-up pre-emphasis circuit 121 may emphasize a portion of the waveform of the transmission signal DQ. In some embodiments, the pull-up pre-emphasis circuit 121 may generate a driving signal controlling an output driver (not illustrated) of the pull-up pre-emphasis circuit 121. The driving signal may turn on or turn off the output driver (not illustrated) of the pull-up pre-emphasis circuit 121. When the output driver (not illustrated) of the pull-up pre-emphasis circuit 121 is turned on, the output driver (not illustrated) may emphasize a portion of the waveform of the transmission signal DQ.

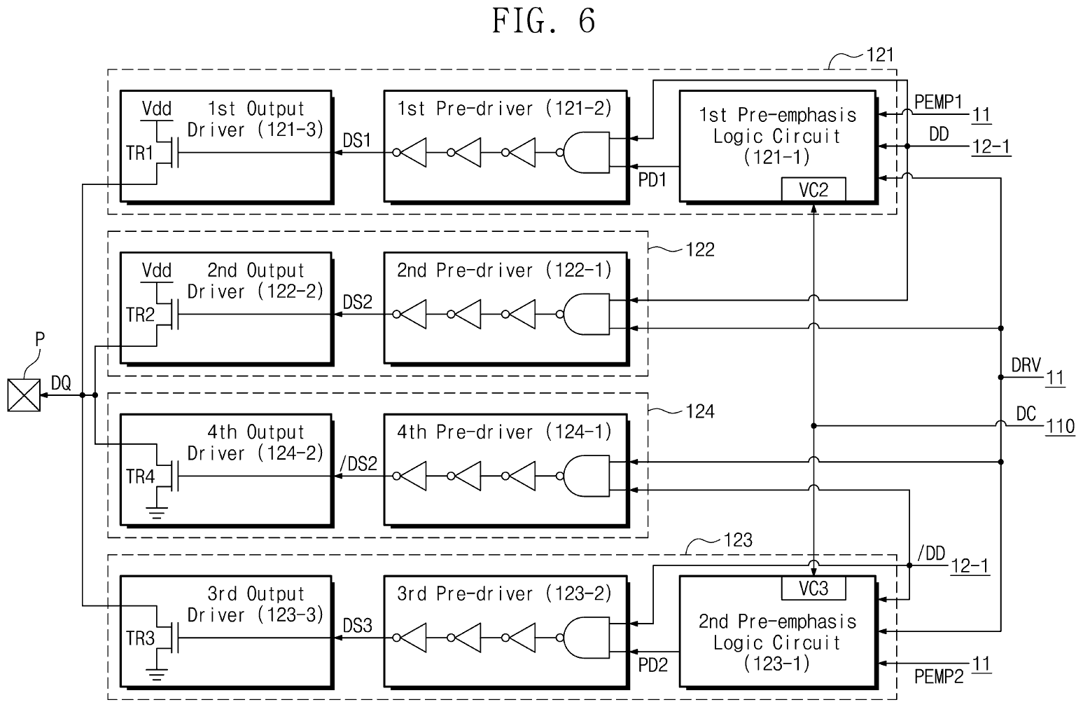

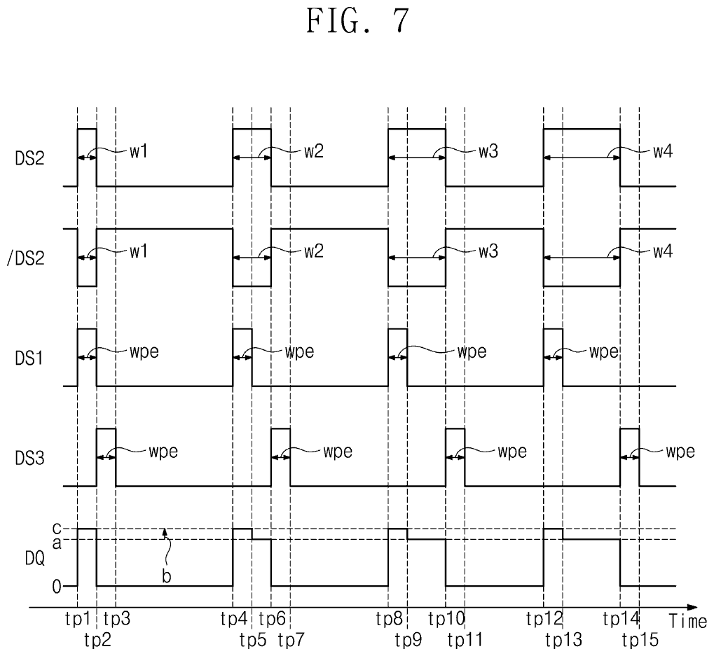

The pull-up pre-emphasis circuit 121 may generate a driving control signal controlling the output driver (not illustrated) of the pull-up pre-emphasis circuit 121 based on a first pre-emphasis control signal PEMP1, the data signal DD, and a driving control signal DRV. The driving control signal of the pull-up pre-emphasis circuit 121 will be described in detail with reference to FIGS. 6 and 7.

The pull-up pre-emphasis circuit 121 may include the second variable capacitor VC2. The second variable capacitor VC2 may operate based on the delay code DC. For example, the capacitance value of the second variable capacitor VC2 may change based on the delay code DC. In some embodiments, the pull-up pre-emphasis circuit 121 may delay the data signal DD based on the second variable capacitor VC2 and may generate a driving signal (not illustrated) including high-level pulses during a time period by which the data signal DD is delayed. For example, the pull-up pre-emphasis circuit 121 may delay the data signal DD as much as a time period similar to the 1 UI, based on the capacitance value of the second variable capacitor VC2 changed depending on the delay code DC and may generate the driving signal (not illustrated) including high-level pulses during the time period by which the data signal DD is delayed. The pull-up pre-emphasis circuit 121 may generate the driving signal (not illustrated) with a pulse width similar to the 1 UI through the second variable capacitor VC2, based on the data signal DD and the delay code DC. That is, to generate the drive signal (not illustrated), the pull-up pre-emphasis circuit 121 may not require additional circuits or signals except for the second variable capacitor VC2 and the delay code DC. Accordingly, the memory interface circuit 100 including the pull-up pre-emphasis circuit 121 may accurately perform the low-power pre-emphasis operation on the transmission signal DQ with a relatively small chip area. The pull-up pre-emphasis circuit 121 will be described in detail with reference to FIG. 6.

The pull-up driving circuit 122 may buffer the data signal DD. For example, the pull-up driving circuit 122 may buffer the data signal DD based on the driving control signal DRV. In some embodiments, the pull-up driving circuit 122 may generate a driving signal for controlling an output driver (not illustrated) of the pull-up driving circuit 122 based on the driving control signal DRV and the data signal DD. The output driver (not illustrated) of the pull-up driving circuit 122 may be turned on or turned off based on the driving signal which the pull-up driving circuit 122 generates. When the output driver (not illustrated) of the pull-up driving circuit 122 is turned on, the output driver (not illustrated) may pull up the transmission signal DQ to a power supply voltage Vdd. The pull-up driving circuit 122 will be described in detail with reference to FIG. 6.

The pull-down pre-emphasis circuit 123 may perform the pre-emphasis operation on the transmission signal DQ based on the driving control signal DRV, the data signal DD, and a second pre-emphasis control signal PEMP2. For example, the pull-down pre-emphasis circuit 123 may emphasize a portion of the waveform of the transmission signal DQ based on the driving control signal DRV, the data signal DD, and the second pre-emphasis control signal PEMP2. In some embodiments, the pull-down pre-emphasis circuit 123 may generate a driving signal controlling an output driver (not illustrated) of the pull-down pre-emphasis circuit 123. The driving signal may turn on or turn off the output driver (not illustrated) of the pull-down pre-emphasis circuit 123. When the output driver (not illustrated) of the pull-down pre-emphasis circuit 123 is turned on, the output driver (not illustrated) may emphasize a portion of the waveform of the transmission signal DQ (e.g., may pull down the transmission signal DQ).

Because the pull-down pre-emphasis circuit 123 and the pull-down driving circuit 124 are similar to the pull-up pre-emphasis circuit 121 and the pull-up driving circuit 122, and thus, additional description will be omitted to avoid redundancy.

FIG. 3 is a block diagram of a calibration loop circuit according to some embodiments of the present disclosure. Referring to FIG. 3, the calibration loop circuit 110 may generate the delay code DC. The calibration loop circuit 110 may provide the generated delay code DC to the transmitter 120. The calibration loop circuit 110 may include a first pulse generator 111, a pre-emphasis logic circuit 112, a first pre-driver 113, a second pulse generator 114, a second pre-driver 115, a flip-flop circuit 116, and a logic circuit 117.

The first pulse generator 111 may generate a first pulse signal PUL1 based on the first clock signal CK1. For example, the first pulse generator 111 may generate the first pulse signal PUL1 based on the first clock signal CK1 including pulses with a reference pulse width. The reference pulse width may be identical to the 2 UI. In some embodiments, the first pulse signal PUL1 may include pulses whose pulse widths are identical or similar to the reference pulse width. The first pulse generator 111 may include a first AND gate AND1. The first AND gate AND1 may perform a first logic operation on the first clock signal CK1 and the power supply voltage Vdd and may generate the first pulse signal PUL1 as a result of the first logic operation. However, the first AND gate AND1 is provided only for better understanding and is not intended to limit the scope of the present disclosure. The first pulse generator 111 may include any other components capable of performing the first logic operation on the first clock signal CK1 and the power supply voltage Vdd. The first pulse generator 111 may provide the first pulse signal PUL1 to the pre-emphasis logic circuit 112 and the first pre-driver 113.

The pre-emphasis logic circuit 112 may include the first variable capacitor VC1. The first variable capacitor VC1 may operate based on the delay code DC. For example, the capacitance value of the first variable capacitor VC1 may increase or decrease based on the delay code DC. The pre-emphasis logic circuit 112 may generate a delay signal DP. For example, the pre-emphasis logic circuit 112 may generate the delay signal DP by delaying and inverting the first pulse signal PUL1. The pre-emphasis logic circuit 112 may generate the delay signal DP by delaying and inverting the first pulse signal PUL1 by using the capacitance, the parasitic capacitance, and the internal resistance of the first variable capacitor VC1. The pre-emphasis logic circuit 112 may provide the delay signal DP to the first pre-driver 113.

In some embodiments, the pre-emphasis logic circuit 112 may delay the first pulse signal PUL1 depending on the capacitance value of the first variable capacitor VC1. For example, when the capacitance value of the first variable capacitor VC1 increases based on the delay code DC, the pre-emphasis logic circuit 112 may further delay the first pulse signal PUL1 to generate the delay signal DP. Also, when the capacitance value of the first variable capacitor VC1 decrease based on the delay code DC, the pre-emphasis logic circuit 112 may delay the first pulse signal PUL1 less to generate the delay signal DP.

The first pre-driver 113 may generate a third pulse signal PUL3. For example, the first pre-driver 113 may perform the logic operation on the first pulse signal PUL1 and the delay signal DP to generate the third pulse signal PUL3. In some embodiments, the third pulse signal PUL3 may correspond to a result of the AND logic operation on the first pulse signal PUL1 and the delay signal DP. The first pre-driver 113 may include a first NAND (not-AND) gate NAND1, a first inverter INV1, a second inverter INV2, and a third inverter INV3. However, the first NAND gate NAND1 and the first to third inverters INV1 to INV3 are provided only for better understanding and are not intended to limit the scope of the present disclosure. The first pre-driver 113 may include any other components capable of performing the same logic operation or may include inverters, the number of which is different from the number of inverters described above, so as to perform the same logic operation.

The first NAND gate NAND1, the first inverter INV1, the second inverter INV2, and the third inverter INV3 may sequentially perform logic operations on the first pulse signal PUL1 and the delay signal DP. As a result, the first pre-driver 113 may perform the AND logic operation on the first pulse signal PUL1 and the delay signal DP.

The first pre-driver 113 may perform the AND logic operation on the first pulse signal PUL1 and the delay signal DP obtained by inverting and delaying the first pulse signal PUL1 such that there is generated the third pulse signal PUL3 having the high level during a time period by which the first pulse signal PUL1 is delayed and having the low level during the remaining time period. That is, the first pre-driver 113 may generate, as the third pulse signal PUL3, a signal whose pulse width corresponds to the phase difference of the first pulse signal PUL1 and the delay signal DP (or corresponds to a time period by which the delay signal DP is delayed with respect to the first pulse signal PUL1). The first pre-driver 113 may provide the third pulse signal PUL3 to the flip-flop circuit 116.

The second pulse generator 114 may generate a second pulse signal PUL2 based on the first clock signal CK1 and the second clock signal CK2. For example, the second pulse generator 114 may generate the second pulse signal PUL2 including pulses with a pulse width of the 1 UI corresponding to the phase difference of the first clock signal CK1 and the second clock signal CK2. The phase difference of the first clock signal CK1 and the second clock signal CK2 may be 90°, and the 1 UI may correspond to the phase difference of 90°. The second pulse generator 114 may include a second AND gate AND2. The second AND gate AND2 may perform a second logic operation on the first clock signal CK1 and the second clock signal CK2 and may generate the second pulse signal PUL2 as a result of the second logic operation. However, the second AND gate AND2 is provided only for better understanding and is not intended to limit the scope of the present disclosure. The second pulse generator 114 may include any other components capable of performing the second logic operation on the first clock signal CK1 and the second clock signal CK2. The second pulse generator 114 may provide the second pulse signal PUL2 to the second pre-driver 115.

The second pre-driver 115 may generate a reference signal REF. For example, the second pre-driver 115 may generate the reference signal REF by performing the logic operation on the second pulse signal PUL2 and the power supply voltage Vdd. Accordingly, the reference signal REF may be identical or similar to the second pulse signal PUL2. The second pre-driver 115 may include a second NAND gate NAND2, a fourth inverter INV4, a fifth inverter INV5, and a sixth inverter INV6. However, the second NAND gate NAND2 and the fourth to sixth inverters INV4 to INV6 are provided only for better understanding and are not intended to limit the scope of the present disclosure. The second pre-driver 115 may include any other components capable of performing the same logic operation or may include inverters, the number of which is different from the number of inverters described above, so as to perform the same logic operation.

The second NAND gate NAND2, the fourth inverter INV4, the fifth inverter INV5, and the sixth inverter INV6 may sequentially perform logic operations on the second pulse signal PUL2 and the power supply voltage Vdd. As a result, the second pre-driver 115 may perform the AND logic operation on the second pulse signal PUL2 and the power supply voltage Vdd.

The second pre-driver 115 may generate the reference signal REF with a pulse width of the 1 UI by performing the AND logic operation on the power supply voltage Vdd and the second pulse signal PUL2 with a pulse width of the 1 UI corresponding to the phase difference of the first clock signal CK1 and the second clock signal CK2. The second pre-driver 115 may provide the reference signal REF to the flip-flop circuit 116.

The flip-flop circuit 116 may generate a result signal LR based on the third pulse signal PUL3 and the reference signal REF. The flip-flop circuit 116 may be implemented with a D flip-flop. In some embodiments, the flip-flop circuit 116 may be implemented with a falling edge-triggered D flip-flop. The flip-flop circuit 116 may generate the result signal LR based on the third pulse signal PUL3 and the reference signal REF. For example, the flip-flop circuit 116 may receive the reference signal REF as a data signal and may receive the third pulse signal PUL3 as a clock signal.

In some embodiments, the flip-flop circuit 116 may generate the result signal LR based on a result of comparing pulse widths of the reference signal REF and the third pulse signal PUL3. For example, when the pulse width of the third pulse signal PUL3 is equal to or less than the pulse width of the reference signal REF, the flip-flop circuit 116 may generate the result signal LR of the high level. Also, when the pulse width of the third pulse signal PUL3 is greater than the pulse width of the reference signal REF, the flip-flop circuit 116 may generate the result signal LR of the low level. That is, the flip-flop circuit 116 may determine whether the pulse width of the third pulse signal PUL3 is greater than the pulse width of the reference signal REF.

In other words, because the third pulse signal PUL3 indicates a time period by which the first pulse signal PUL1 is delayed by the first variable capacitor VC1, the flip-flop circuit 116 may determine whether the time period by which the first pulse signal PUL1 is delayed is greater than the 1 UI. The flip-flop circuit 116 may provide the result signal LR to the logic circuit 117.

The logic circuit 117 may generate or change the delay code DC. For example, the logic circuit 117 may generate or change the delay code DC based on a logic value of the result signal LR. The logic circuit 117 may be implemented with a counter. The logic circuit 117 may provide the generated or changed delay code DC to the first variable capacitor VC1. The logic circuit 117 may operate based to the first clock signal CK1. However, the first clock signal CK1 is provided only for better understanding and is not intended to limit the scope of the present disclosure. The logic circuit 117 may operate based at least one of the first clock signal CK1 to a fourth clock signal CK4 or may operate based on any other signal.

In some embodiments, when the input result signal LR is at the high level, the logic circuit 117 may increase a value of the delay code DC as much as “1”. For example, when the input result signal LR is at the high level, the logic circuit 117 may increase the value of the delay code DC as much as “1”, that is, “0” to “1”. The value of the delay code DC may be implemented by a binary number. Next, the logic circuit 117 may provide the changed delay code DC to the first variable capacitor VC1.

In some embodiments, when the input result signal LR is at the low level, the logic circuit 117 may decrease the value of the delay code DC as much as “1”. For example, when the input result signal LR is at the low level, the logic circuit 117 may decrease the value of the delay code DC as much as “1”, that is, “3” to “2”. Next, the logic circuit 117 may provide the decreased delay code DC to the first variable capacitor VC1.

In some embodiments, when the input result signal LR is at the low level, the logic circuit 117 may decrease the value of the delay code DC as much as “1” and may lock the delay code DC. To lock the delay code DC may indicate to lock the delay code DC such that the value of the delay code DC is not changed regardless of the logic level (e.g., the high level or the low level) of the input result signal LR. That is, when the pulse width of the third pulse signal PUL3 is greater than the pulse width of the reference signal REF, the logic circuit 117 may decrease the value of the delay code DC as much as “1” and may lock the delay code DC.

However, to increase or decrease the value of the delay code DC as much as “1” is provided only for better understanding and is not intended to limit the scope of the present disclosure. The logic circuit 117 may increase or decrease the value of the delay code DC as much as an arbitrary natural number more than “1”.

In some embodiments, when the logic circuit 117 locks the delay code DC, the pulse width of the third pulse signal PUL3 may be equal to or less than but similar to the pulse width of the reference signal REF (identical to the 1 UI). The logic circuit 117 may provide the locked delay code DC to the transmitter 120. That is, the calibration loop circuit 110 may generate the delay code DC such that the transmitter 120 is capable of generating a signal with a pulse width similar to the 1 UI (e.g., a driving signal capable of controlling the output driver of the pull-up pre-emphasis circuit 121 of FIG. 2).

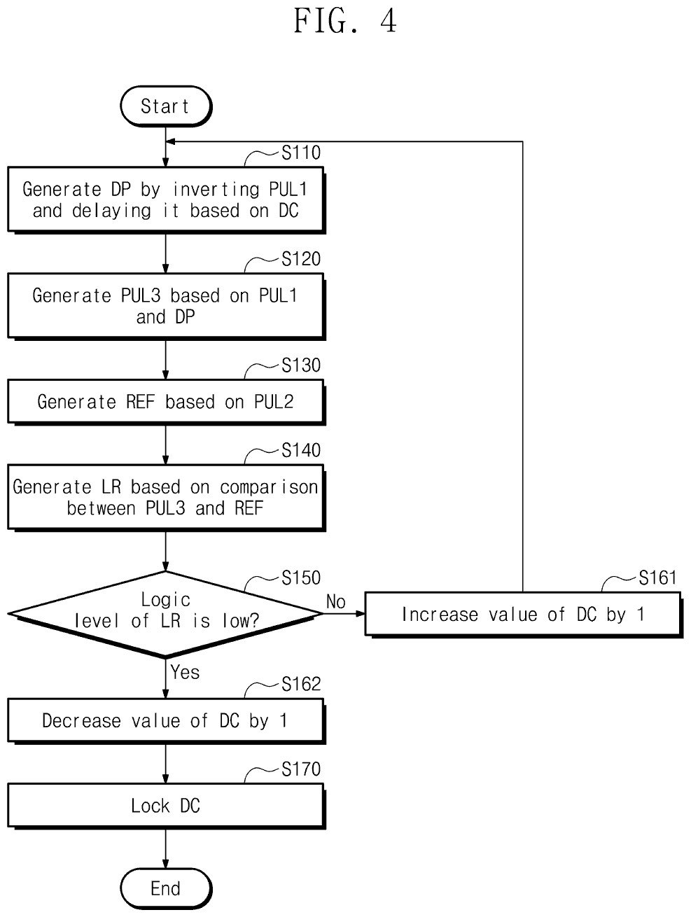

FIG. 4 is a flowchart describing a method of operating a calibration loop circuit according to some embodiments of the present disclosure. Referring to FIG. 4, the calibration loop circuit 110 of FIG. 3 may change a value of the delay code DC.

In operation S110, the calibration loop circuit may generate the delay signal DP by inverting and delaying the first pulse signal PUL1 based on the delay code DC. For example, the calibration loop circuit may change the capacitance value of the first variable capacitor VC1 of FIG. 2 based on the delay code DC. Next, the calibration loop circuit may generate the delay signal DP by inverting the first pulse signal PUL1 and delaying the inverted first pulse signal PUL1 based on the changed capacitance value of the first variable capacitor VC1.

In operation S120, the calibration loop circuit may generate the third pulse signal PUL3 based on the first pulse signal PUL1 and the delay signal DP. For example, the calibration loop circuit may compare the first pulse signal PUL1 with the delay signal DP generated by delaying and inverting the first pulse signal PUL1. The calibration loop circuit may generate the third pulse signal PUL3 which is at the high level during a time period by which the delay signal DP is delayed with respect to the first pulse signal PUL1 and is at the low level in the remaining time period.

In operation S130, the calibration loop circuit may generate the reference signal REF based on the second pulse signal PUL2. For example, the calibration loop circuit may generate the reference signal REF with the same pulse width as the second pulse signal PUL2 by performing the AND logic operation on the second pulse signal PUL2 and the power supply voltage. The pulse width of the reference signal REF may be the 1 UI.

In operation S140, the calibration loop circuit may generate the result signal LR based on the comparison between the third pulse signal PUL3 and the reference signal REF. For example, the calibration loop circuit may compare the difference between the pulse width of the third pulse signal PUL3 and the pulse width of the reference signal REF and may generate the result signal LR based on a comparison result. That is, because the third pulse signal PUL3 indicates a time period by which the first pulse signal PUL1 is delayed by the first variable capacitor VC1 of FIG. 2, the calibration loop circuit may determine whether the time period by which the first pulse signal PUL1 is delayed is greater than the 1 UI.

When the pulse width of the third pulse signal PUL3 is equal to or less than the pulse width of the reference signal REF, the calibration loop circuit may generate the result signal LR of the high level. Also, when the pulse width of the third pulse signal PUL3 is greater than the pulse width of the reference signal REF, the calibration loop circuit may generate the result signal LR of the low level.

In operation S150, the calibration loop circuit may determine whether the result signal LR is at the low level. For example, the calibration loop circuit may determine whether the result signal LR determined depending on whether the pulse width of the third pulse signal PUL3 is greater than the pulse width of the reference signal REF is at the low level.

In operation S161, the calibration loop circuit may increase the value of the delay code DC as much as “1” in response to determining that the result signal LR is not at the low level. Then, the calibration loop circuit may again perform operation S110 based on the changed delay code DC. In operation S162, the calibration loop circuit may decrease the value of the delay code DC as much as “1” in response to determining that the result signal LR is at the low level. In operation S170, the calibration loop circuit 110 may lock the changed delay code DC. That is, the calibration loop circuit may lock the delay code DC such that the pulse width of the third pulse signal PUL3 is not greater than the 1 UI but is similar to the 1 UI. Afterwards, the calibration loop circuit may provide the delay code DC to the transmitter 120 of FIG. 2.

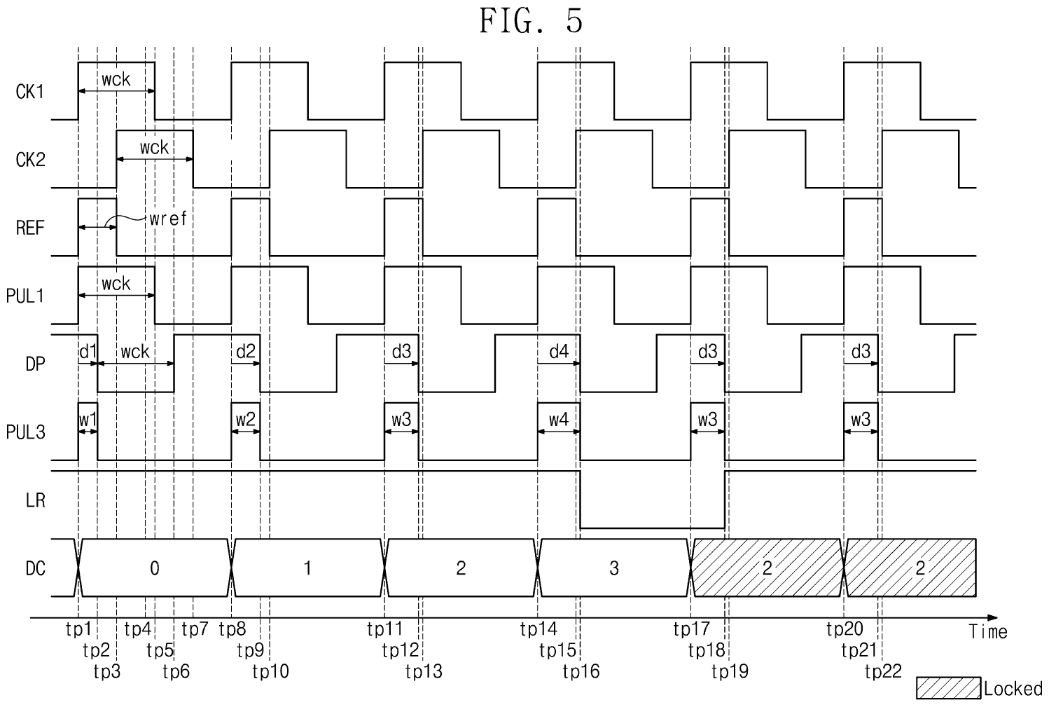

FIG. 5 is a timing diagram describing signals which a calibration loop circuit according to some embodiments of the present disclosure generates. Referring to FIG. 5, the horizontal axis represents a time, and the vertical axis represents a logic level.

Each of the first clock signal CK1 and the second clock signal CK2 may include pulses each having a uniform pulse width at a regular time interval. The pulse widths of the first clock signal CK1 and the second clock signal CK2 may be named a clock width wck. The clock width wck may be the 2 UI. The phase difference of the first clock signal CK1 and the second clock signal CK2 may be 90°. For example, the first clock signal CK1 may rise to the high level at a first time point tp1 and may fall to the low level at a fifth time point tp5. Also, the second clock signal CK2 may rise to the high level at a third time point tp3 and may fall to the low level at a seventh time point tp7. A time interval from the first time point tp1 to the third time point tp3 may correspond to the phase difference of 90°.

The reference signal REF may correspond to the phase difference of the first clock signal CK1 and the second clock signal CK2. For example, the reference signal REF may rise to the high level at the first time point tp1 and may fall to the low level at the third time point tp3. The pulse width of the reference signal REF may be a reference width wref. The reference signal REF may include pulses each having a uniform pulse width corresponding to the reference width wref (or the 1 UI) at a regular time interval.

The first pulse signal PUL1 may be identical or similar to the first clock signal CK1. Because the first pulse signal PUL1 is a result of the AND operation on the first clock signal CK1 and the power supply voltage, the first pulse signal PUL1 may include pulses similar to the pulses of the first clock signal CK1. The pulse width of the first pulse signal PUL1 may be the clock width wck identical to the pulse width of the first clock signal CK1 or the second clock signal CK2. The first pulse signal PUL1 may rise to the high level at the first time point tp1 and may fall to the low level at the fifth time point tp5.

The delay signal DP may be generated by inverting and delaying the first pulse signal PUL1 by using the first variable capacitor VC1 of FIG. 3. The delay signal DP may have the same pulse width (e.g., the clock width wck) as the first pulse signal PUL1, but the phase of the delay signal DP may be delayed with respect to the first pulse signal PUL1. For example, the delay signal DP may fall to the low level at a second time point tp2 delayed with respect to the first time point tp1 as much as a first delay time d1 and may rise to the high level at a sixth time point tp6 delayed with respect to the fifth time point tp5 as much as the first delay time d1.

For example, the capacitance value of the first variable capacitor VC1 of FIG. 3 may change based on the delay code DC. Delay times (e.g., first to fourth delay times d1 to d4) by which the delay signal DP is delayed with respect to the first pulse signal PUL1 may change depending on the changed capacitance value. For example, the delay signal DP may fall to the low level at the second time point tp2 delayed with respect to the first time point tp1 as much as the first delay time d1, may fall to the low level at a ninth time point tp9 delayed with respect to an eighth time point tp8 as much as the second delay time d2, may fall to the low level at a twelfth time point tp12 delayed with respect to an eleventh time point tp11 as much as the third delay time d3, and may fall to the low level at a sixteenth time point tp16 delayed with respect to a fourteenth time point tp14 as much as the fourth delay time d4. The first delay time d1, the second delay time d2, the third delay time d3, and the fourth delay time d4 may be different from each other.

The third pulse signal PUL3 may be a signal which is at the high level during the first to fourth delay times d1 to d4. That is, the third pulse signal PUL3 may include pulses having pulse widths respectively corresponding to the time periods by which the first pulse signal PUL1 is delayed. For example, the third pulse signal PUL3 may be at the high level during a time period from tp1 to tp2, a time period from tp8 to tp9, a time period from tp11 to tp12, and a time period from tp14 to tp16.

Because the first pulse signal PUL1 is delayed by the first variable capacitor VC1, the third pulse signal PUL3 may be generated based on a value of the delay code DC by which the capacitance value of the first variable capacitor VC1 is changed.

The result signal LR may be at the high level when the pulse width of the third pulse signal PUL3 is equal to or less than the pulse width of the reference signal REF. Also, the result signal LR may be at the low level when the pulse width of the third pulse signal PUL3 is greater than the pulse width of the reference signal REF. For example, the result signal LR may be at the high level from the first time point tp1 to the sixteenth time point tp16. At the sixteenth time point tp16, in response to determining that the pulse width of the third pulse signal PUL3 is greater than the pulse width of the reference signal REF, the result signal LR may fall to the low level at the sixteenth time point tp16 (at the falling edge of the third pulse signal PUL3). Also, the result signal LR may be at the low level from the sixteenth time point tp16 to an eighteenth time point tp18, and at the eighteenth time point tp18 (at the falling edge of the third pulse signal PUL3), the result signal LR may rise to the high level in response to the pulse width of the third pulse signal PUL3 is equal to or less than the pulse width of the reference signal REF.

The delay code DC may have the same period and phase as the first clock signal CK1 or the reference signal REF. For example, the delay code DC may have one value (e.g., “0”) from the first time point tp1 to the eighth time point tp8 and may have another value (e.g., “1”) from the eighth time point tp8 to the eleventh time point tp11.

The value of the delay code DC may be an integer of 0 or more. The delay code DC may be implemented by a binary number. The value of the delay code DC may rise or fall depending on the logic level of the result signal LR, for each period (for each rising edge of the first clock signal CK1 or the reference signal REF). For example, when the result signal LR maintains the high level from the first time point tp1 to the eighth time point tp8, the value of the delay code DC may rise from “0” to “1” at the eighth time point tp8.

In some embodiments, when the result signal LR maintains the high level, the value of the delay code DC may increase as much as “1” at a next rising edge of the first clock signal CK1 or the reference signal REF. Also, when the result signal LR transitions from the high level to the low level, the value of the delay code DC may decrease as much as “1” at a next rising edge of the first clock signal CK1 or the reference signal REF and may then be locked. For example, when the result signal LR transitions from the high level to the low level at the sixteenth time point tp16, the value of the delay code DC may decrease from “3” to “2” as much as “1” at the seventeenth time point tp17 and may then be locked at “2” (a hatched region). Accordingly, after the seventeenth time point tp17, the value of the delay code DC may be maintained at “2” regardless of the logic level of the result signal LR

FIG. 6 is a block diagram of a transmitter according to some embodiments of the present disclosure. Referring to FIG. 6, the transmitter 120 may generate the transmission signal DQ based on the data signal DD and the inverted data signal/DD. The transmitter 120 may include the pull-up pre-emphasis circuit 121, the pull-up driving circuit 122, the pull-down pre-emphasis circuit 123, and the pull-down driving circuit 124. The pull-up pre-emphasis circuit 121 may operate based on the data signal DD, the delay code DC, the driving control signal DRV, and the first pre-emphasis control signal PEMP1. The pull-up pre-emphasis circuit 121 may include a first pre-emphasis logic circuit 121-1, a first pre-driver 121-2, and a first output driver 121-3.

The first pre-emphasis logic circuit 121-1 may generate a first data delay signal PD1 based on the data signal DD, the delay code DC, the driving control signal DRV, and the first pre-emphasis control signal PEMP1. For example, the first pre-emphasis logic circuit 121-1 may generate the first data delay signal PD1 by inverting and delaying the data signal DD in response to the driving control signal DRV of the high level and the first pre-emphasis control signal PEMP1 of the high level.

In some embodiments, the first pre-emphasis logic circuit 121-1 may generate the first data delay signal PD1 by inverting the data signal DD and delaying the inverted data signal based on the delay code DC. For example, the first pre-emphasis logic circuit 121-1 may receive the delay code DC from the calibration loop circuit 110 of FIG. 2. The received delay code DC may have a value for delaying the data signal DD as much as a time period similar to the 1 UI (but equal to or less than the 1 UI). Next, the first pre-emphasis logic circuit 121-1 may delay the data signal DD as much as the time period similar to the 1 UI, based on the value of the delay code DC.

The first pre-emphasis logic circuit 121-1 may include the second variable capacitor VC2 operating based on the delay code DC. The capacitance value of the second variable capacitor VC2 may increase or decrease depending on the value of the delay code DC. In some embodiments, an operation of the second variable capacitor VC2 may be identical or similar to the operation on the first variable capacitor VC1. That is, the second variable capacitor VC2 may operate to be identical or similar to the operation performed by the first variable capacitor VC1 based on the delay code DC.

The first pre-emphasis logic circuit 121-1 may provide the first data delay signal PD1 to the first pre-driver 121-2. The first pre-driver 121-2 may generate a first driving signal DS1 based on the data signal DD and the first data delay signal PD1. For example, the first pre-driver 121-2 may receive the data signal DD from the volatile memory device 12-1, may receive the first data delay signal PD1 from the first pre-emphasis logic circuit 121-1, and may generate the first driving signal DS1 by performing the AND logic operation on the data signal DD and the first data delay signal PD1.

In some embodiments, the first pre-driver 121-2 may perform the AND logic operation on the data signal DD and the first data delay signal PD1 obtained by inverting the data signal DD and delaying the inverted data signal as much as a time period similar to the 1 UI (but equal to or less than the 1 UI). Accordingly, as in the third pulse signal PUL3 of FIG. 3, the first pre-driver 121-2 may generate the first driving signal DS1 which is at the high level during a time period by which the first data delay signal PD1 is delayed with respect to the data signal DD. Components of the first pre-driver 121-2 are similar to the components of the first pre-driver 113 of FIG. 3, and thus, additional description will be omitted to avoid redundancy. The first pre-driver 121-2 may provide the first driving signal DS1 to the first output driver 121-3.

The first output driver 121-3 may operate based on the first driving signal DS1. The first output driver 121-3 may be implemented with a pull-up circuit. For example, the first output driver 121-3 may pull up the transmission signal DQ based on the first driving signal DS 1. The first output driver 121-3 may include a first transistor TR1. An example in which the first transistor TR1 is implemented with an N-channel metal oxide semiconductor (NMOS) transistor is illustrated, but the present disclosure is not limited thereto.

Like the third pulse signal PUL3 of FIGS. 3 and 5, the first driving signal DS1 may include pulses whose pulse widths are similar to the 1 UI (but are equal to or less than the 1 UI). The first driving signal DS 1 may be the same phase as the data signal DD. That is, the first driving signal DS1 may rise to the high level at the rising edge of the data signal DD. The first transistor TR1 may be turned on based on the first driving signal DS1 of the high level and may pull up the transmission signal DQ to the power supply voltage Vdd.

The pull-up driving circuit 122 may operate based on the data signal DD and the driving control signal DRV. The pull-up driving circuit 122 may buffer the data signal DD in response to the driving control signal DRV of the high level.

The pull-up driving circuit 122 may include a second pre-driver 122-1 and a second output driver 122-2. The second pre-driver 122-1 may generate a second driving signal DS2 by performing the AND operation on the data signal DD and the driving control signal DRV. That is, the second pre-driver 122-1 may generate the second driving signal DS2 identical or similar to the data signal DD, in response to the driving control signal DRV of the high level.

Components of the second pre-driver 122-1 are similar to the components of the second pre-driver 115 of FIG. 3, and thus, additional description will be omitted to avoid redundancy. The second pre-driver 122-1 may provide the second driving signal DS2 to the second output driver 122-2. The second output driver 122-2 may operate based on the second driving signal DS2. The second output driver 122-2 may be implemented with a pull-up circuit. For example, the second output driver 122-2 may pull up the transmission signal DQ based on the second driving signal DS2. The second output driver 122-2 may include a second transistor TR2. An example in which the second transistor TR2 is implemented with an NMOS transistor is illustrated, but the present disclosure is not limited thereto. The second transistor TR2 may be turned on based on the second driving signal DS2 of the high level and may pull up the transmission signal DQ to the power supply voltage Vdd.

The pull-down pre-emphasis circuit 123 may perform the pre-emphasis operation on the transmission signal DQ based on the driving control signal DRV, the inverted data signal/DD, and the second pre-emphasis control signal PEMP2. The pull-down pre-emphasis circuit 123 may include a second pre-emphasis logic circuit 123-1, a third pre-driver 123-2, and a third output driver 123-3. The second pre-emphasis logic circuit 123-1 may generate a second data delay signal PD2 based on the inverted data signal/DD, the delay code DC, the driving control signal DRV, and the second pre-emphasis control signal PEMP2. For example, the second pre-emphasis logic circuit 123-1 may generate the second data delay signal PD2 by inverting and delaying the inverted data signal/DD in response to the driving control signal DRV of the high level and the second pre-emphasis control signal PEMP2 of the high level.

The second pre-emphasis logic circuit 123-1 may include the third variable capacitor VC3 operating based on the delay code DC. The capacitance value of the third variable capacitor VC3 may increase or decrease depending on the value of the delay code DC. In some embodiments, an operation of the third variable capacitor VC3 may be identical or similar to the operation of the first variable capacitor VC1. That is, the third variable capacitor VC3 may operate to be identical or similar to the operation performed by the first variable capacitor VC 1 based on the delay code DC.

The second pre-emphasis logic circuit 123-1 may provide the second data delay signal PD2 to the third pre-driver 123-2. And, the third pre-driver 123-2 may generate a third driving signal DS3 based on the inverted data signal/DD and the second data delay signal PD2. For example, the third pre-driver 123-2 may receive the inverted data signal/DD from the volatile memory device 12-1, may receive the second data delay signal PD2 from the second pre-emphasis logic circuit 123-1, and may generate the third driving signal DS3 by performing the AND logic operation on the inverted data signal/DD and the second data delay signal PD2.

Components of the third pre-driver 123-2 are similar to the components of the first pre-driver 121-2, and thus, additional description will be omitted to avoid redundancy. The third pre-driver 123-2 may provide the third driving signal DS3 to the third output driver 123-3. The third output driver 123-3 may operate based on the third driving signal DS3. The third output driver 123-3 may be implemented with a pull-down circuit. For example, the third output driver 123-3 may pull down the transmission signal DQ based on the third driving signal DS3. The third output driver 123-3 may include a third transistor TR3. The third driving signal DS3 may include pulses whose pulse widths are similar to the 1 UI (but are equal to or less than the 1 UI). The third driving signal DS3 may rise to the high level at the rising edge of the inverted data signal/DD. The third transistor TR3 may be turned on based on the third driving signal DS3 of the high level and may pull down the transmission signal DQ.

The pull-down driving circuit 124 may include a fourth pre-driver 124-1 and a fourth output driver 124-2. The fourth pre-driver 124-1 may generate a second inverted driving signal/DS2 by performing the AND operation on the inverted data signal/DD and the driving control signal DRV. That is, the fourth pre-driver 124-1 may generate the second inverted driving signal/DS2 identical or similar to the inverted data signal/DD, in response to the driving control signal DRV of the high level.

Components of the fourth pre-driver 124-1 are similar to the components of the second pre-driver 122-1, and thus, additional description will be omitted to avoid redundancy. The fourth pre-driver 124-1 may provide the second inverted driving signal/DS2 to the fourth output driver 124-2.

The fourth output driver 124-2 may operate based on the second inverted driving signal/DS2. The fourth output driver 124-2 may be implemented with a pull-down circuit. For example, the fourth output driver 124-2 may pull down the transmission signal DQ based on the second inverted driving signal/DS2. The fourth output driver 124-2 may include a fourth transistor TR4. The fourth transistor TR4 may be turned on based on the second inverted driving signal/DS2 of the high level and may pull down the transmission signal DQ.

FIG. 7 is a timing diagram describing signals which a transmitter according to some embodiments of the present disclosure generates. Referring to FIG. 7, the transmission signal DQ may be generated by the first to fourth output drivers 121-3, 122-2, 123-3, and 124-2 of FIG. 6, which are controlled by the first driving signal DS1, the second driving signal DS2, the second inverted driving signal/DS2, and the third driving signal DS3. In FIG. 7, the horizontal axis represents a time, and the vertical axis represents a voltage level.

The second driving signal DS2 may include pulses having arbitrary pulse widths. As described with reference to FIG. 6, the second driving signal DS2 may be identical or similar to the data signal DD of FIG. 6. For example, the second driving signal DS2 may include high-level pulses having a first width w1, a second width w2, a third width w3, and a fourth width w4, respectively. The second driving signal DS2 of the high level may turn on the second output driver 122-2 of FIG. 6.

The second inverted driving signal/DS2 may be an inverted version of the second driving signal DS2. For example, the second inverted driving signal/DS2 may include low-level pulses having the first width w1, the second width w2, the third width w3, and the fourth width w4, respectively. The second inverted driving signal/DS2 of the low level may turn off the fourth output driver 124-2 of FIG. 6.

The first driving signal DS1 may include pulses each having a pre-emphasis width wpe at regular time intervals. The pre-emphasis width wpe may be similar to the 1UI. The first driving signal DS1 may rise to the high level at the rising edge of the second driving signal DS2 (or the data signal DD). For example, the first driving signal DS1 may rise to the high level at a first time point tp1, a fourth time point tp4, an eighth time point tp8, and a twelfth time point tp12, at which the second driving signal DS2 (or the data signal DD) has the rising edge. The first driving signal DS1 of the high level may turn on the first output driver 121-3 of FIG. 6.

The third driving signal DS3 may include pulses each having the pre-emphasis width wpe at regular time intervals. The third driving signal DS3 may rise to the high level at the falling edge of the second driving signal DS2 (or the data signal DD). For example, the third driving signal DS3 may rise to the high level at a second time point tp2, a sixth time point tp6, a tenth time point tp10, and a fourteenth time point tp14, at which the second driving signal DS2 (or the data signal DD) has the falling edge. The third driving signal DS3 of the high level may turn on the third output driver 123-3 of FIG. 6.

The transmission signal DQ may be generated based on that the first to fourth output drivers 121-3, 122-2, 123-3, and 124-2 of FIG. 6 are turned on or turned off. For example, the voltage level of the transmission signal DQ may be determined when the transmission signal DQ is pulled up or pulled down by the turn-on or turn-off of the first to fourth output drivers 121-3, 122-2, 123-3, and 124-2 of FIG. 6.

The voltage level of the transmission signal DQ may be “0”, “a”, or “c”. In an embodiment, “a” and “c” are a real number, and “c” is greater than “a”. The voltage level of the transmission signal DQ is only provided for better understanding and is not intended to limit the scope of the present disclosure. The voltage level of the transmission signal DQ may have any other real number value, as well as “0”, “a”, or “c”.

The pre-emphasis operation on the transmission signal DQ may be performed by the first output driver 121-3 or the third output driver 123-3 of FIG. 6, which is turned on by the first driving signal DS1 or the third driving signal DS3. For example, during a time period from tp4 to tp5, when the first driving signal DS1 and the second driving signal DS2 are at the high level, the voltage level of the transmission signal DQ may be “c”. Next, during a time period from tp5 to tp6, when the first driving signal DS1 is at the low level and the second driving signal DS2 is at the high level, the voltage level of the transmission signal DQ may be “a”. That is, when the first driving signal DS1 is turned on, the voltage level of the transmission signal DQ may be “c” which is greater than “a” as much as “b”. In other words, the voltage level of the transmission signal DQ may be further emphasized as much as “b”. This may mean that the pre-emphasis operation on the transmission signal DQ is performed. In an embodiment, “b” is a positive real number.

Also, during a time period from tp2 to tp3, when the third driving signal DS3 is at the high level, the voltage level of the transmission signal DQ may be “0”. At the second time point tp2, the falling of the voltage level of the transmission signal DQ may be delayed by the capacitance or the like of the channel. When the third driving signal DS3 is at the high level, the third output driver 123-3 of FIG. 6 may be turned on, and thus, the voltage level of the transmission signal DQ may be pulled down to “0” by the third output driver 123-3. That is, when the third driving signal DS3 is at the high level, the voltage level of the transmission signal DQ may be pulled down, and thus, the pre-emphasis operation on the transmission signal DQ may be performed. As the pre-emphasis operation on the transmission signal DQ is performed, the distortion which is caused while the transmission signal DQ is transmitted to an external host device through the channel may be minimized.

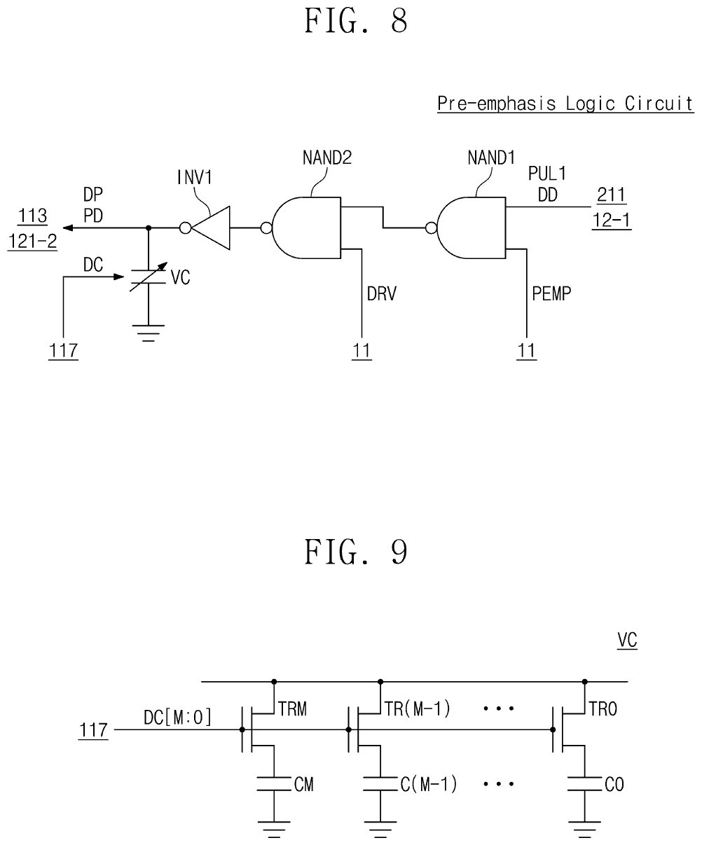

FIG. 8 is a diagram describing a pre-emphasis logic circuit according to some embodiments of the present disclosure. Referring to FIG. 8, a pre-emphasis logic circuit may include a first NAND gate NAND1, a second NAND gate NAND2, a first inverter INV1, and a variable capacitor VC. The pre-emphasis logic circuit may be one of some embodiments of the pre-emphasis logic circuit 112 of FIG. 3 or the first pre-emphasis logic circuit 121-1 of FIG. 6. The components of the pre-emphasis logic circuit of FIG. 8 are only provided for better understanding and are not intended to limit the scope of the present disclosure. The pre-emphasis logic circuit may include any other components performing the same logic operations or functions.

The pre-emphasis logic circuit may perform a first AND logic operation on the first pulse signal PUL1 and the pre-emphasis control signal PEMP or the data signal DD and the pre-emphasis control signal PEMP, may perform a second AND logic operation on a result of the first AND logic operation and the driving control signal DRV, and may generate the delay signal DP or the data delay signal PD by inverting a result of the second AND logic operation.

In some embodiments, the pre-emphasis logic circuit may generate the delay signal DP or the data delay signal PD by delaying the first pulse signal PUL1 or the data signal DD by using the internal resistance, the parasitic capacitance, and the capacitance of the variable capacitor VC. The variable capacitor VC (e.g., one of the first to third variable capacitors VC1 to VC3 of FIG. 2) may operate based on the delay code DC.

FIG. 9 is a diagram describing a variable capacitor according to some embodiments of the present disclosure. Referring to FIG. 9, the variable capacitor VC may include a plurality of transistors TR0 to TRM and a plurality of capacitors C0 to CM. In an embodiment, “M” may be a natural number. The capacitance value of the variable capacitor VC may be a sum of capacitance values of capacitors connected to turned-on transistors among the plurality of transistors TR0 to TRM. The variable capacitor VC may be one of some embodiments of the first to third variable capacitors VC1 to VC3 of FIG. 2. The variable capacitor VC may operate based on the delay code DC. The delay code DC may be formed of (M+1) bits to control the plurality of transistors TR0 to TRM, respectively. For example, the plurality of transistors TR0 to TRM may be respectively turned on or turned off based on the corresponding bits of the delay code DC.

Each of the plurality of capacitors C0 to CM may be connected to the ground and the corresponding one of the plurality of transistors TR0 to TRM. In some embodiments, the plurality of capacitors C0 to CM may have the same or different capacitance values.

In some embodiments, when “M” is 2, the delay code DC may be expressed by a 3-bit binary number. For example, when the value of the delay code DC is 3 whose binary number is “011”, the 0-th and first transistors TR0 and TR1 may be turned on, and the second transistor TR2 may be turned off. Accordingly, the capacitance value of the variable capacitor VC may be a sum of capacitance values of the 0-th and first capacitors C0 and C1 respectively connected to the 0-th and first transistors TR0 and TR1.

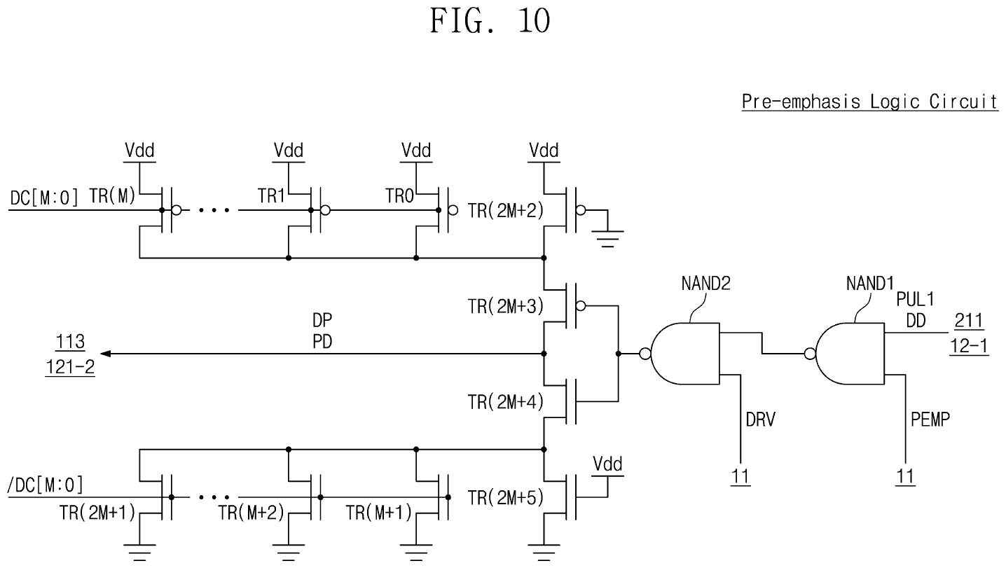

FIG. 10 is a diagram describing a pre-emphasis logic circuit according to some embodiments of the present disclosure. Referring to FIG. 10, a pre-emphasis logic circuit may include a first NAND gate NAND1, a second NAND gate NAND2, and 0-th to (2M+5)-th transistors TR0 to TR(2M+5). Herein, “M” is an arbitrary natural number. The pre-emphasis logic circuit may be one of some embodiments of the pre-emphasis logic circuit 112 of FIG. 3 or the first pre-emphasis logic circuit 121-1 of FIG. 6. The components of the pre-emphasis logic circuit of FIG. 10 are only provided for better understanding and are not intended to limit the scope of the present disclosure. The pre-emphasis logic circuit may include any other components performing the same logic operations or functions.

The pre-emphasis logic circuit may perform a first AND logic operation on the first pulse signal PUL1 and the pre-emphasis control signal PEMP or the data signal DD and the pre-emphasis control signal PEMP, may perform a second AND logic operation on a result of the first AND logic operation and the driving control signal DRV, and may generate the delay signal DP or the data delay signal PD by inverting a result of the second AND logic operation.

In some embodiments, the pre-emphasis logic circuit may generate the delay signal DP or the data delay signal PD by delaying the first pulse signal PUL1 or the data signal DD by using resistances, internal resistances, and parasitic capacitances of the 0-th to (2M+5)-th transistors TR0 to TR(2M+5).

In some embodiments, the 0-th to M-th transistors TRO to TRM may operate based on the delay code DC[M:0]. The delay code DC may be formed of (M+1) bits to control the 0-th to M-th transistors TR0 to TRM, respectively. For example, 0-th to M-th transistors TR0 to TRM may be respectively turned on or turned off based on the corresponding bits of the delay code DC[M:0]. The 0-th to M-th transistors TR0 to TRM may be implemented with a PMOS transistor. However, the 0-th to M-th transistors TR0 to TRM implemented with a PMOS transistor are only provided for better understanding and are not intended to limit the scope of the present disclosure.

In some embodiments, the (M+1)-th to (2M+1)-th transistors TR(M+1) to TR(2M+1) may operate based on the inverted delay code/DC[M:0]. For example, the (M+1)-th to (2M+1)-th transistors TR(M+1) to TR(2M+1) may be respectively turned on or turned off based on the corresponding bits of the inverted delay code/DC[M:0]. The (M+1)-th to (2M+1)-th transistors TR(M+1) to TR(2M+1) may be implemented with an NMOS transistor. However, the (M+1)-th to (2M+1)-th transistors TR(M+1) to TR(2M+1) implemented with an NMOS transistor are only provided for better understanding and are not intended to limit the scope of the present disclosure.

In some embodiments, the delay code DC[M:0] may be generated by the calibration loop circuit 110 of FIGS. 2 and 3 including the pre-emphasis logic circuit of FIG. 10 to control the 0-th to M-th transistors TR0 to TRM. The inverted delay code/DC [M:0] may be an inverted version of the delay code DC[M:0].

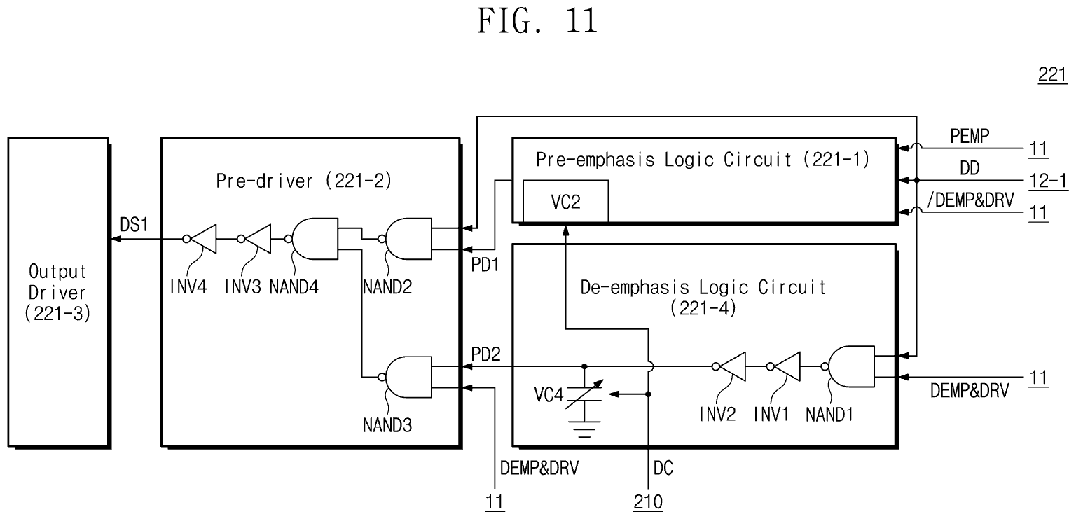

FIG. 11 is a diagram describing a pull-up pre-emphasis circuit according to some embodiments of the present disclosure. Referring to FIG. 11, a pull-up pre-emphasis circuit 221 may include a pre-emphasis logic circuit 221-1, a pre-driver 221-2, an output driver 221-3, and a de-emphasis logic circuit 221-4. The pre-emphasis logic circuit 221-1, the pre-driver 221-2, and the output driver 221-3 may respectively be similar to the first pre-emphasis logic circuit 121-1, the first pre-driver 121-2, and the first output driver 121-3 of FIG. 6, and thus, additional description will be omitted to avoid redundancy.

The pull-up pre-emphasis circuit 221 may operate based on the first driving signal DS1. For example, the pull-up pre-emphasis circuit 221 may perform the pre-emphasis operation or a de-emphasis operation on the transmission signal DQ of FIG. 2 based on the first driving signal DS1 of the high level. The de-emphasis operation on the transmission signal DQ may be performed to distort a portion of the transmission signal DQ. For example, the pre-emphasis operation on the transmission signal DQ may be performed to emphasize a portion of the waveform of the transmission signal DQ, while the de-emphasis operation on the transmission signal DQ may be performed to attenuate the portion of the waveform of the transmission signal DQ.

The pre-emphasis logic circuit 221-1 may generate the first data delay signal PD1 based on the data signal DD, the pre-emphasis control signal PEMP, a product signal/DEMP&DRV of an inverted de-emphasis control signal and a driving signal, and the delay code DC. For example, the pre-emphasis logic circuit 221-1 may generate the first data delay signal PD1 by inverting and delaying the data signal DD based on the delay code DC in response to the pre-emphasis control signal PEMP of the high level and the product signal/DEMP&DRV of an inverted de-emphasis control signal and a driving signal of the high level.

The pre-driver 221-2 may include a second NAND gate NAND2, a third NAND gate NAND3, a fourth NAND gate NAND4, and third and fourth inverters INV3 and INV4. However, the third and fourth NAND gates NAND3 and NAND4 and the third and fourth inverters INV3 and INV4 are only provided for better understanding and are not intended to limit the scope of the present disclosure. The pre-driver 221-2 may include any other components capable of performing the same or similar logic operations or may include inverters, the number of which is different from the number of inverters described above, so as to perform the same or similar logic operations.

The pre-driver 221-2 may generate the first driving signal DS1 based on the data signal DD, the first data delay signal PD1, the second data delay signal PD2, and the product signal DEMP&DRV of a de-emphasis control signal and a driving signal. For example, the pre-driver 221-2 may perform a first logic operation on the data signal DD and the first data delay signal PD1, may perform a second logic operation on the second data delay signal PD2 and the product signal DEMP&DRV of a de-emphasis control signal and a driving signal, may perform a third logic operation on a result of the first logic operation and a result of the second logic operation, and may generate the first driving signal DS1 by inverting a result of the third logic operation plural times.

The de-emphasis logic circuit 221-4 may include a first NAND gate NAND1, first and second inverters INV1 and INV2, and a fourth variable capacitor VC4. The de-emphasis logic circuit 221-4 may generate the second data delay signal PD2 based on the data signal DD, the product signal DEMP&DRV of a de-emphasis control signal and a driving signal, and the delay code DC. However, the first NAND gate NAND1, the first and second inverters INV1 and INV2, and the fourth variable capacitor VC4 are only provided for better understanding and are not intended to limit the scope of the present disclosure. The de-emphasis logic circuit 221-4 may include any other components capable of performing the same or similar logic operations.

In some embodiments, the first NAND gate NAND1 may perform a fourth logic operation on the data signal DD and the product signal DEMP&DRV of a de-emphasis control signal and a driving signal. Afterwards, the first and second inverters INV1 and INV2 may generate the second data delay signal PD2 by sequentially inverting a result of the fourth logic operation.

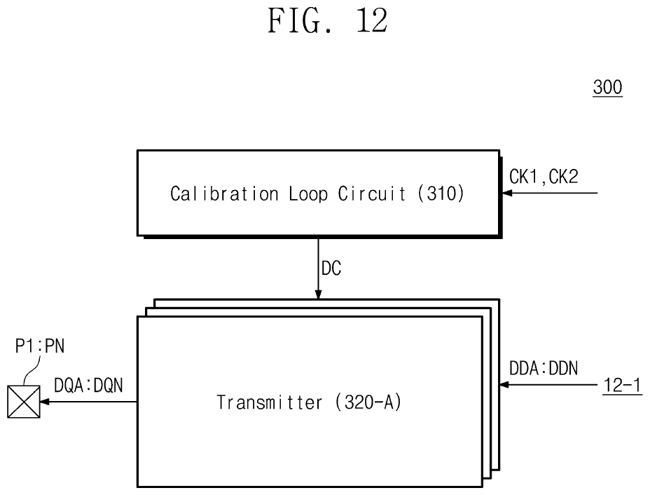

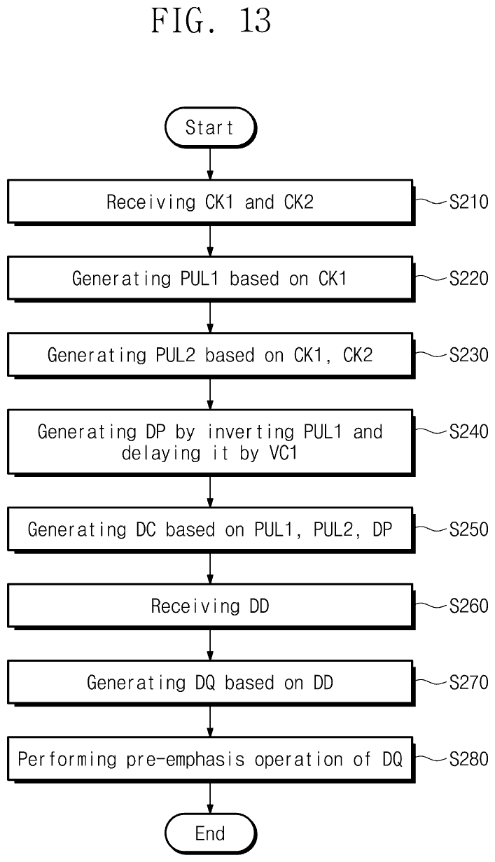

FIG. 12 is a block diagram of a memory interface circuit according to some embodiments of the present disclosure. Referring to FIG. 12, a memory interface circuit 300 may include a calibration loop circuit 310 and a plurality of transmitters 320-A to 320-N. The calibration loop circuit 310 is similar to the calibration loop circuit 110 of FIG. 2, and each of the plurality of transmitters 320-A to 320-N is similar to the transmitter 120 of FIG. 2. Thus, additional description will be omitted to avoid redundancy. The plurality of transmitters 320-A to 320-N may be similar to each other. The calibration loop circuit 310 may provide the delay code DC to each of the plurality of transmitters 320-A to 320-N.

The plurality of transmitters 320-A to 320-N may respectively receive a plurality of data signals DDA to DDN from the volatile memory device 12-1. The transmitters 320-A to 320-N may respectively generate a plurality of transmission signals DQA to DQN based on the plurality of data signals DDA to DDN and the delay code DC. The plurality of transmitters 320-A to 320-N may provide the plurality of transmission signals DQA to DQN to a plurality of pads P1 to PN, respectively.

FIG. 13 is a flowchart describing a method of operating a memory interface circuit according to some embodiments of the present disclosure. Referring to FIG. 13, the memory interface circuit 100 of FIG. 2 may perform the pre-emphasis operation on the transmission signal DQ.

In operation S210, the memory interface circuit may receive the first clock signal CK1 and the second clock signal CK2. For example, the memory interface circuit may receive the first clock signal CK1 and the second clock signal CK2 which are different in phase but have pulse widths having the same periods (and identical to the 2 UI). In operation S220, the memory interface circuit may generate the first pulse signal PUL1 based on the first clock signal CK1. For example, the memory interface circuit may generate the first pulse signal PUL1 whose pulse width is identical or similar to the 2 UI, based on the first clock signal CK1. In operation S230, the memory interface circuit may generate the second pulse signal PUL2 based on the first clock signal CK1 and the second clock signal CK2. For example, the memory interface circuit may generate the second pulse signal PUL2 corresponding to the phase difference of the first clock signal CK1 and the second clock signal CK2. The second pulse signal PUL2 may be identical in phase to the first clock signal CK1 and may include pulses each having a pulse width of the 1 UI. In operation S240, the memory interface circuit may generate the delay signal DP by inverting the first pulse signal PUL1 and delaying the inverted first pulse signal PUL1 by using the first variable capacitor VC1. In operation S250, the memory interface circuit may generate the delay code DC for controlling the second variable capacitor VC2 based on the first pulse signal PUL1, the second pulse signal PUL2, and the delay signal DP. For example, to generate the first driving signal DS1 of FIG. 6, whose pulse width is similar to the 1 UI, based on the first pulse signal PUL1, the second pulse signal PUL2, and the delay signal DP, the memory interface circuit may generate the delay code DC for controlling the second variable capacitor VC2.

In some embodiments, the memory interface circuit may generate the third pulse signal PUL3 of FIG. 3 corresponding to the phase difference of the first pulse signal PUL1 and the delay signal DP. Also, the memory interface circuit may generate the reference signal REF of FIG. 3, which has a pulse width of the 1 UI, based on the second pulse signal PUL2. Next, the memory interface circuit may generate the result signal LR of FIG. 3 based on a result of comparing the third pulse signal PUL3 and the reference signal REF of FIG. 3. The memory interface circuit may generate the delay code DC based on a logic level of the result signal LR of FIG. 3.

In operation S260, the memory interface circuit may receive the data signal DD. For example, the memory interface circuit may receive the data signal DD from the volatile memory device 12-1 of FIG. 1. In operation S270, the memory interface circuit may generate the transmission signal DQ based on the data signal DD. In operation S280, the memory interface circuit may perform the pre-emphasis operation on the transmission signal DQ. The memory interface circuit may perform the pre-emphasis operation on the transmission signal DQ, and thus, the distortion capable of occurring when the transmission signal DQ is transmitted to the host device may be minimized.

In the above embodiments, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

According to an embodiment of the present disclosure, a memory interface circuit performing a pre-emphasis operation and a method of operating the same are provided. Also, a memory interface circuit which performs a pre-emphasis operation capable of minimizing the distortion of data transmission by performing the pre-emphasis operation by using a data signal uniformly delayed by a variable capacitor and a method of operating the same are provided.

While the present disclosure has been described with reference to embodiments thereof, it will be apparent to those of ordinary skill in the art that various changes and modifications may be made thereto without departing from the spirit and scope of the present disclosure as set forth in the following claims.

1. A memory interface circuit, comprising:
a calibration loop circuit configured to generate: a first pulse signal in response to a first clock signal, a second pulse signal in response to the first clock signal and a second clock signal, a delay signal by inverting and delaying the first pulse signal using a first variable capacitor, and a delay code based on the first and second pulse signals and the delay signal; and
a first transmitter configured to generate a transmission signal in response to a data signal received from a volatile memory device, and perform a pre-emphasis operation on the transmission signal based on a capacitance of a second variable capacitor, which changes in response to changes in the delay code.

2. The memory interface circuit of claim 1, wherein the calibration loop circuit includes:
a first pulse generator configured to generate the first pulse signal based on the first clock signal;
a pre-emphasis logic circuit including the first variable capacitor, and configured to invert the first pulse signal and to generate the delay signal by delaying the inverted first pulse signal by using the first variable capacitor;
a first pre-driver configured to generate a third pulse signal by performing a first logic operation on the delay signal and the first pulse signal;
a second pulse generator configured to generate the second pulse signal based on the first clock signal and the second clock signal;
a second pre-driver configured to generate a reference signal based on the second pulse signal;
a flip-flop circuit configured to generate a result signal by performing a second logic operation on the third pulse signal and the reference signal; and
a logic circuit configured to generate the delay code based on the result signal.

3. The memory interface circuit of claim 2,
wherein the calibration loop circuit includes the first variable capacitor and the first transmitter includes the second variable capacitor; and
wherein pulse widths of the second pulse signal and the reference signal are 1unit interval (1 UI) corresponding to a phase difference of the first clock signal and the second clock signal.

4. The memory interface circuit of claim 2, wherein a capacitance value of the first variable capacitor changes in response to changes in the delay code.

5. The memory interface circuit of claim 2, wherein the flip-flop circuit is configured to:
generate the result signal at a high level in response to determining that a pulse of the third pulse signal has a pulse width equal to or less than a pulse of the reference signal; and
generate the result signal at a low level in response to determining that the pulse of the third pulse signal has a pulse width greater than the pulse of the reference signal.

6. The memory interface circuit of claim 2, wherein the logic circuit is configured to increase a value of the delay code in response to receiving the result signal of a high level from the flip-flop circuit and to provide the delay code with the increased value to the pre-emphasis logic circuit.

7. The memory interface circuit of claim 2, wherein the logic circuit is configured to decrease a value of the delay code in response to receiving the result signal of a low level from the flip-flop circuit and to provide the delay code with the decreased value to the first transmitter.

8. The memory interface circuit of claim 1, wherein the first transmitter includes:
a pull-up pre-emphasis circuit configured to generate a first data delay signal by delaying the data signal by using the second variable capacitor based on a driving control signal and a first pre-emphasis control signal, and to generate a first driving signal based on the data signal and the first data delay signal; and
a pull-up driving circuit configured to generate a second driving signal based on the driving control signal and the data signal.

9. The memory interface circuit of claim 8, wherein the pull-up pre-emphasis circuit includes:
a pre-emphasis logic circuit including the second variable capacitor operating based on the delay code, and configured to generate the first data delay signal by delaying the data signal by using the second variable capacitor in response to the driving control signal and the first pre-emphasis control signal;
a first pre-driver configured to generate the first driving signal by performing a first logic operation on the data signal and the first data delay signal; and
a first output driver configured to pull up the transmission signal in response to that the first driving signal is at a high level.

10. The memory interface circuit of claim 9,
wherein the pull-up pre-emphasis circuit further includes a de-emphasis logic circuit configured to generate a second data delay signal based on the data signal in response to a de-emphasis control signal and the driving control signal;
wherein the de-emphasis logic circuit includes:
a first logic gate configured to perform a second logic operation on the data signal and a result of an AND logic operation on the de-emphasis control signal and the driving control signal;
a first inverter configured to invert a result of the second logic operation;
a second inverter configured to generate the second data delay signal by inverting a result of inverting the result of the second logic operation; and
a third variable capacitor configured to operate based on the delay code; and
wherein the pre-driver includes:
a second logic gate configured to perform a third logic operation on the data signal and the first data delay signal;
a third logic gate configured to perform a fourth logic operation on the second data delay signal and a result of an AND logic operation on the de-emphasis control signal and the driving control signal;
a fourth logic gate configured to perform a fifth logic operation on a result of the third logic operation and a result of the fourth logic operation; and
a fourth inverter and a fifth inverter configured to generate the first driving signal by sequentially inverting the result of the fourth logic operation.

11. The memory interface circuit of claim 8, wherein the pull-up driving circuit includes:
a second pre-driver configured to generate a second driving signal based on the data signal in response to the driving control signal; and
a second output driver configured to pull up the transmission signal in response to that the second driving signal is at a high level.

12. The memory interface circuit of claim 8, wherein the first driving signal is identical in phase to the data signal and includes pulses each having a uniform pulse width.

13. The memory interface circuit of claim 9, wherein the pre-emphasis logic circuit further includes:
a first logic gate configured to perform a first logic operation on the data signal and the first pre-emphasis control signal;
a second logic gate configured to perform a second logic operation on a result of the first logic operation and the driving control signal; and
an inverter configured to generate the first data delay signal by inverting a result of inverting a result of the second logic operation.

14. The memory interface circuit of claim 8, wherein the first transmitter further includes:
a pull-down pre-emphasis circuit configured to generate a second data delay signal by delaying an inverted data signal by using a third variable capacitor based on the driving control signal and a second pre-emphasis control signal, to generate a third driving signal based on the inverted data signal and the second data delay signal, and to pull down the transmission signal in response to that the third driving signal is at a high level; and
a pull-down driving circuit configured to generate a second inverted driving signal based on the driving control signal and the inverted data signal and to pull down the transmission signal in response to that the second inverted driving signal is at the high level.

15. The memory interface circuit of claim 1, wherein the second variable capacitor includes:
a plurality of transistors configured to operate based on the delay code; and
a plurality of capacitors respectively connected to the plurality of transistors.

16. The memory interface circuit of claim 1,
wherein the memory interface circuit further includes second to N-th transmitters configured to respectively receive second to N-th data signals from the volatile memory device; and
wherein the second to N-th transmitters are configured to respectively receive the delay code from the calibration loop circuit, to respectively generate second to N-th transmission signals based on the second to N-th data signals, and to respectively perform pre-emphasis operations of the second to N-th transmission signals.

17. A method of operating a memory interface circuit including a pad, a calibration loop circuit, and a transmitter, the method comprising:
receiving, by the calibration loop circuit, a first clock signal and a second clock signal;
generating, by the calibration loop circuit, a first pulse signal based on the first clock signal;
generating, by the calibration loop circuit, a second pulse signal based on the first clock signal and the second clock signal;
generating, by the calibration loop circuit, a delay signal by inverting the first pulse signal and delaying the inverted first pulse signal by using a first variable capacitor;
generating, by the calibration loop circuit, a delay code for controlling a second variable capacitor based on the first pulse signal, the second pulse signal, and the delay signal;
receiving, by the transmitter, a data signal from a volatile memory device;
generating, by the transmitter, a transmission signal based on the data signal; and
performing, by the transmitter, a pre-emphasis operation on the transmission signal based on a capacitance value of the second variable capacitor, which is changed depending on the delay code; and
wherein the calibration loop circuit includes the first variable capacitor, and the transmitter includes the second variable capacitor.

18. The method of claim 17, wherein the generating of the delay code includes:
generating, by the calibration loop circuit, a third pulse signal by performing a first logic operation on the first pulse signal and the delay signal;
generating, by the calibration loop circuit, a reference signal based on the second pulse signal;
generating, by the calibration loop circuit, a result signal by performing a second logic operation on the third pulse signal and the reference signal; and
generating, by the calibration loop circuit, the delay code based on the result signal.

19. The method of claim 17, wherein the performing of the pre-emphasis operation includes:
generating, by the transmitter, a data delay signal by delaying the data signal by using the second variable capacitor;
generating, by the transmitter, a driving signal based on the data signal and the data delay signal; and
performing, by the transmitter, the pre-emphasis operation by pulling up the transmission signal in response to that the driving signal is at a high level.

20. A memory interface circuit comprising:
a pad configured to be connected to an external device;
a calibration loop circuit including a first group of a plurality of transistors; and
a transmitter connected to the pad and including a second group of a plurality of transistors;
wherein the calibration loop circuit is configured to:
receive a first clock signal and a second clock signal;
generate a first pulse signal based on the first clock signal;
generate a second pulse signal based on the first clock signal and the second clock signal;
generate a delay signal by delaying the first pulse signal by using the first group of the plurality of transistors; and
generate a delay code for controlling the second group of the plurality of transistors based on the first pulse signal, the second pulse signal, and the delay signal; and
wherein the transmitter is configured to:
receive a data signal from a volatile memory device;
generate a transmission signal based on the data signal; and
perform a pre-emphasis operation on the transmission signal by using the second group of the plurality of transistors controlled by the delay code.

21. (canceled)
